(19) United States
(12) Patent Application Publication
(10) Pub. No.: US 2021/0333237 A1
(43) Pub. Date: Oct. 28, 2021

(54) DISTORTION-FREE BOUNDARY EXTENSION METHOD FOR ONLINE WAVELET DENOISING

(71) Applicant: HARBIN ENGINEERING UNIVERSITY, Heilongjiang Province (CN)

(72) Inventors: Lanyong ZHANG, Heilongjiang Province (CN); Menglin WANG, Heilongjiang Province (CN); Sheng LIU, Heilongjiang Province (CN); Chengyu LI, Heilongjiang Province (CN)

(73) Assignee: HARBIN ENGINEERING UNIVERSITY, Heilongjiang Province (CN)

(21) Appl. No.: 17/202,787

(22) Filed: Mar. 16, 2021

(30) Foreign Application Priority Data
Apr. 27, 2020 (CN) 202010345709.0

(51) Int. Cl. G01N 27/82

(52) U.S. Cl. CPC G01N 27/82

(57) ABSTRACT

The present disclosure provides a distortion-free boundary extension method for online wavelet denoising. The method includes: S1: acquiring a signal segment xₙ, and performing a distortion-free boundary extension on the signal segment to obtain M+N+L data; S2: decomposing a lifting wavelet of the N data to be denoised into j layers to acquire approximation coefficients and detail coefficients; S3: calculating a threshold of each layer of the lifting wavelet; S4: thresholding the detail coefficients of each layer to obtain estimated values of the detail coefficients; S5: performing wavelet reconstruction by the approximation coefficients and the estimated values of the detail coefficients obtained by thresholding to obtain a reconstructed signal after denoising; and S6: outputting data.

### TECHNICAL FIELD

The present disclosure relates to a method of online wavelet signal denoising, in particular to a method of online wavelet denoising based on a distortion-free boundary extension.

### BACKGROUND

Featuring high detection sensitivity, fast detection speed, low requirements for sample surface cleanliness, low cost and simple operation, magnetic flux leakage (MFL) is widely used in the field of non-destructive testing (NDT) of ferromagnetic materials. As the core of the MFL system, signal processing is expected to acquire useful signals in a complex field environment, remove noise and finally realize quantitative analysis of defect signals. This requires noise reduction processing for MFL signals interfered by noise.

Wavelet denoising is an excellent signal denoising algorithm, which is a successful application of the wavelet transform theory in the signal denoising field. The wavelet transform is defined on double infinite intervals. However, the signal processed in practical applications is usually of finite length. Therefore, there is a distortion problem caused by the boundary interference. The post-processing in an offline environment (such as a personal computer (PC)) can process a long signal data segment at a time, and the boundary interference can often be ignored. However, for the real-time processing in an online denoising environment (such as an embedded environment), due to the real-time requirements, the signal segment processed at a time is short, and the boundary effect will be prominent, resulting in a decrease in the denoising effect. Even in occasions with high real-time requirements, boundary point signals are often of interest.

The boundary interference exists in both the traditional Mallat algorithm and the lifting algorithm. Although these algorithms have different generation mechanisms, they have the same negative impact on the accuracy of wavelet decomposition and reconstruction.

In the Mallat algorithm, when the filter coefficients are convolved with a finite-length signal sequence, a null error will occur at the boundary, so it is necessary to extend the boundary of the finite-length sequence. The boundary extension methods mainly include a zero-filling method, a periodic extension method and a symmetric extension method. These three extension methods have their own advantages and disadvantages, but they all inevitably cause an algorithmic interference which leads to boundary distortion.

In the lifting algorithm, the wavelet lifting scheme is realized by several prediction and update steps. Because the lifting wavelet is a non-causal wavelet (except the Haar wavelet), historical data and future data are often needed in the prediction and update steps of the current point. If the input signal sequence is of finite length, the left boundary of the sequence will inevitably lack historical data, and the right boundary thereof will inevitably lack future data, making it impossible to predict or update the boundary points. Therefore, the lifting algorithm also needs to extend the boundary, thereby causing an algorithmic interference which leads to boundary distortion.

In order to reduce the impact of unreliable values on the reconstruction accuracy, scholars have proposed some schemes, which are divided into two categories. The first category is to construct a more suitable boundary extension scheme, such as least squares fitting (LSF) boundary extension and Volterra series boundary extension based on zero extension, periodic extension and symmetric extension. The boundary extension scheme is easy to implement, but its suppression effect on the boundary interference is limited. The second category is to introduce a boundary wavelet, that is, not to extend, but to use prediction and update operators at the boundary point that are different from those at the non-boundary point. This scheme can better suppress the boundary interference. However, sometimes there are many boundary points in different cases. In each case, the boundary wavelet needs to be calculated separately, which makes the algorithm extremely complicated and very troublesome to implement.

### SUMMARY

In order to suppress a boundary effect of a wavelet algorithm and overcome the interference defect of the algorithm existing in a traditional extension scheme, an objective of the present disclosure is to provide a distortion-free boundary extension method for online wavelet denoising. The present disclosure completely solves a distortion problem of online wavelet denoising, and completely eliminates the boundary interference of the algorithm.

The present disclosure is implemented as follows.

A distortion-free boundary extension method for online wavelet denoising, including: S1: acquiring a signal segment xₙ, and performing a distortion-free boundary extension on the signal segment to obtain M+N+L data, where M represents a number of historical data used for a distortion-free left extension; L represents a number of future data used for a distortion-free right extension; N represents a number of data to be denoised; S2: decomposing a lifting wavelet of the N data to be denoised into j layers to acquire approximation coefficients sⱼ and detail coefficients {dⱼ, . . . , d₂, d₁}; S3: calculating a threshold Tⱼ of each layer of the lifting wavelet; S4: thresholding the detail coefficients [dⱼ, . . . , d₂, d₁] of each layer to obtain estimated values of the detail coefficients; S5: performing wavelet reconstruction by the approximation coefficients sⱼ and the estimated values of the detail coefficients obtained by thresholding to obtain a reconstructed signal \hat{x}ₙ after denoising; and S6: outputting data.

Further, in S1, the distortion-free boundary extension includes:

S101: reading, when 0<t≤N+L, N+L sampling points from a sampling start point;

S102: symmetrically extending, when N+L<t<N+L+1, a left boundary of the N+L sampling points read for a length of M, and storing in a buffer A; outputting, if buffer A is full, data in A to a next-level wavelet denoiser, and sliding latter M+L data in buffer A to former M+L spaces in the same order, and clearing a remaining buffer space;

S103: letting k be a cycle counter, k=1;

S104: reading, when kN+L+1≤t≤kN+L+N, P sampling points into A; executing S105 if P=N; executing S107 if P<N;

S105: determining, when kN+L+N<t<kN+L+N+1, that buffer A is full, and performing a sliding window operation in A;

S106: letting k=k+1, and returning to S104; and

S107: ending.

Further, in S3, the threshold Tⱼ of each layer of the lifting wavelet is calculated as follows:

$${T}_{j} = \frac{σ \sqrt{2 ln N}}{1 + 1 g j} , j = 1 , 2 , 3 .$$

Further, in S4, the estimated values of the detail coefficients are:

$${\hat{d}}_{j} = {d}_{j} \times 1 {0}^{- {( \frac{{T}_{j}}{\vert {d}_{j} \vert + ɛ} )}^{γ}} ,$$

where, γ=4, ε=10⁻⁵.

Further, a boundary extension in the reconstruction in S5 remains consistent with that in the wavelet decomposition in S2.

Further, in S2, the wavelet is decomposed into j≤3 layers.

A distortion-free boundary extension device for online wavelet denoising, including a distortion-free boundary extension module and a wavelet denoiser, where

the distortion-free boundary extension module is used for performing a distortion-free boundary extension on an acquired signal segment to obtain M+N+L data, where M represents a number of historical data used for a distortion-free left extension; L represents a number of future data used for a distortion-free right extension; N represents a number of data to be denoised;

the wavelet denoiser is used for decomposing a lifting wavelet of the N data to be denoised into j layers to acquire approximation coefficients sⱼ and detail coefficients {dⱼ, . . . , d₂, d₁}, calculating a threshold Tⱼ of each layer of the lifting wavelet, thresholding the detail coefficients {dⱼ, . . . , d₂, d₁} of each layer to obtain estimated values of the detail coefficients, performing wavelet reconstruction by the approximation coefficients sⱼ and the estimated values of the detail coefficients obtained by thresholding to obtain a reconstructed signal \hat{x}ₙ after denoising, and outputting data.

An electronic device, including a memory, a processor and a computer program, where the computer program is stored in the memory, and the processor runs the computer program to execute the following steps:

S1: acquiring a signal segment xₙ, and performing a distortion-free boundary extension on the signal segment to obtain M+N+L data, where M represents a number of historical data used for a distortion-free left extension; L represents a number of future data used for a distortion-free right extension; N represents a number of data to be denoised;

S2: decomposing a lifting wavelet of the N data to be denoised into j layers according to the historical data and the future data to acquire approximation coefficients sⱼ and detail coefficients {dⱼ, . . . , d₂, d₁};

S3: calculating a threshold Tⱼ of each layer of the lifting wavelet;

S4: thresholding the detail coefficients {dⱼ, . . . , d₂, d₁} of each layer to obtain estimated values of the detail coefficients;

S5: performing wavelet reconstruction by the approximation coefficients sⱼ and the estimated values of the detail coefficients obtained by thresholding to obtain a reconstructed signal \hat{x}ₙ after denoising; and

S6: outputting data.

Further, in S1, the distortion-free boundary extension includes:

S101: reading, when 0<t≤N+M, N+M sampling points from a sampling start point;

S102: symmetrically extending, when N+M<t<N+M+1, a left boundary of the N+M sampling points read for a length of M, and storing in a buffer A; outputting, if buffer A is full, data in A to a next-level wavelet denoiser, and sliding latter M+N data in buffer A to former M+N spaces in the same order, and clearing a remaining buffer space;

S103: letting k be a cycle counter, k=1;

S104: reading, when kN+M+1≤t≤kN+M+N, P sampling points into A; executing S105 if P=N ; executing S107 if P<N;

S105: determining, when kN+M+N<t<kN+M+N+1, that buffer A is full, and performing a sliding window operation in A;

S106: letting k=k+1, and returning to S104;

S107: ending; and

S108: acquiring, when performing a distortion-free boundary extension on a k-th signal segment, M historical data in a (k−1)-th signal segment in buffer A, to-be-denoised data in the k-th signal segment and L future data in a (k+1)-th signal segment to generate M+N+L data used for the distortion-free boundary extension on the k-th signal segment.

Further, in S3, the threshold Tⱼ of each layer of the lifting wavelet is calculated as follows:

$${T}_{j} = \frac{σ \sqrt{2 ln N}}{1 + 1 g j} , j = 1 , 2 , 3$$

where, σ represents a standard deviation of noise.

Further, in S4, the estimated values of the detail coefficients obtained by thresholding the detail coefficients {dⱼ, . . . , d₂, d₁} of each layer are:

$${\hat{d}}_{j} = {d}_{j} \times 1 {0}^{- {( \frac{{T}_{j}}{\vert {d}_{j} \vert + ɛ} )}^{γ}}$$

where, γ=4, ε=10⁻⁵.

Further, a boundary extension in the reconstruction in S5 remains consistent with that in the wavelet decomposition in S2.

Further, in S2, the wavelet is decomposed into j≤3 layers.

Further, the S2: decomposing a lifting wavelet of the N data to be denoised into j layers according to the historical data and the future data to acquire approximation coefficients sⱼ and detail coefficients {dⱼ, . . . , d₂, d₁} specifically includes:

acquiring, from the historical data, data used for a left boundary of the N data to be denoised during the j-layer decomposition of the lifting wavelet; and

acquiring, from the future data, data used for a right boundary of the N data to be denoised during the j-layer decomposition of the lifting wavelet.

A readable storage medium, where the readable storage medium stores a computer program; the computer program is executed by a processor to implement the distortion-free boundary extension method for online wavelet denoising.

The present disclosure has the following beneficial effects:

First, the present disclosure provides an online denoising method based on a magnetic flux leakage (MFL) signal. The present disclosure designs a working time series for online denoising targeting an embedded online environment, and proposes a distortion-free extension scheme to eliminate serious boundary interference during online denoising.

Second, the present disclosure proposes a thresholding denoising algorithm based on a lifting wavelet to improve the denoising speed. According to an actual characteristic of the MFL signal, the present disclosure determines the wavelet basis, the number of decomposition layers and the estimated threshold value used for the denoising algorithm. The present disclosure improves a traditional thresholding function, further improves the denoising performance, and achieves a better denoising effect.

Finally, the present disclosure verifies through a series of simulation experiments that the proposed online denoising algorithm is fast, effective, occupies less resources, and has no boundary interference, which fully meets the actual requirements for online denoising of MFL signals.

### BRIEF DESCRIPTION OF DRAWINGS

FIG. 1 shows an extension of one-layer decomposition of a CDF2.2 lifting scheme.

FIG. 2 shows an extension of one-layer reconstruction of the CDF2.2 lifting scheme.

FIG. 3 shows an extension of signal reconstruction after thresholding.

FIG. 4 shows a distortion-free extension scheme for eliminating a boundary interference.

FIG. 5 shows an extension of one-layer decomposition of a CDF2.6 lifting scheme.

FIG. 6 shows a flowchart of a distortion-free boundary extension method for online wavelet denoising.

FIG. 7 shows a working time series of the distortion-free boundary extension scheme.

FIG. 8 shows a comparison of a signal-to-noise ratio (SNR) after processing by a Mallat algorithm and a lifting algorithm.

FIG. 9 shows a comparison of a root-mean-square error (RMSE) after processing by the Mallat algorithm and the lifting algorithm.

FIG. 10 shows a comparison of a denoising performance achieved by different thresholding functions (original SNR=11.1257 db).

FIG. 11 shows a comparison of a denoising performance achieved by different thresholding functions (original SNR=17.1421 db).

FIG. 12 shows a comparison of a denoising performance of different extension schemes.

FIG. 13 shows a comparison of a denoising effect achieved by a hard thresholding method, a flattening method and a method of the present disclosure.

FIG. 14 is a structural diagram of an electronic device.

### DETAILED DESCRIPTION

The acquisition of magnetic flux leakage (MFL) data is realized through a magnetic sensor in an embedded environment, which is an online denoising environment with a high real-time requirement. The online analysis and processing of a signal in such an environment is different from that in an offline denoising environment of a personal computer (PC). In order to successfully implement a selected algorithm online, it is necessary to consider the similarities and differences between the online denoising in the embedded environment and the offline denoising of the PC.

The online denoising of the MFL signal adopts a segmented denoising method. The denoising time of N data must be less than the sampling time of the N data, that is, the value of N is related to the denoising speed of a wavelet denoiser and the sampling speed of the MFL data. Compared with the signal length processed at one time in the PC offline environment, the value of N in online segmented denoising is much smaller, which causes a very serious boundary interference.

The number of distortion points of a lifting wavelet algorithm is discussed below by taking a one-layer CDF2.2 lifting scheme (bior2.2, CDF5/3) wavelet as an example. The CDF2.2 lifting scheme (with a normalization step ignored) is:

$$\{ \begin{matrix}{d}_{l} = {x}_{2 l + 1} - 0.5 \times ( {x}_{2 l} + {x}_{2 l + 2} ) \\ {s}_{l} = {x}_{2 l} + 0.25 \times ( {d}_{l - 1} + {d}_{l} )\end{matrix} \qquad ( 1 \text{-} 1 )$$

For a prediction step dₗ of a current point, a future data x₂ₗ₊₂ is needed; and for an update step s₁, a historical data dₗ₋₁ is needed. Assuming that a finite-length sequence x₂ₗ has eight sampling points, performing one-layer decomposition on it by the CDF2.2 lifting scheme yields four high-frequency detail coefficients dₗ and four low-frequency approximation coefficients sₗ. The decomposition process is shown in FIG. 1.

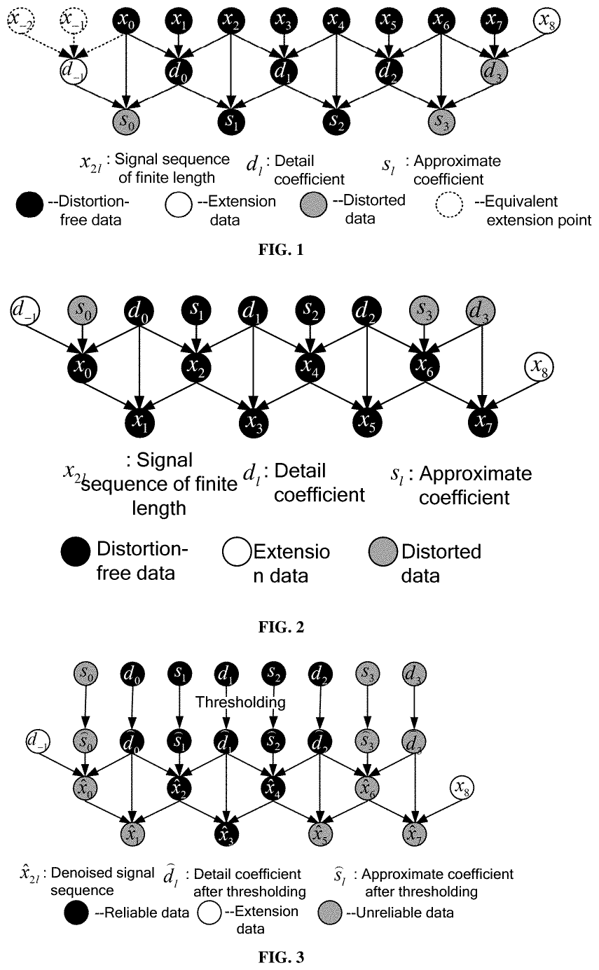

According to the decomposition process, the calculation of detail coefficient d₃ needs x₆ and non-existent x₈. Here, as the boundary is extended by one point of x₈, d₃ distorted by the boundary interference, which in turn causes distortion of approximation coefficients s₃. In the same way, the calculation of s₀ needs d₀ and non-existent d₋₁. Here, as the boundary is extended by one point of d₋₁ or equivalently two points of x₋₁ and x₋₂, s₀ is distorted. In summary, the one-layer decomposition of the CDF2.2 lifting wavelet requires a left extension of two points and a right extension of one point, which results in distortion of one detail coefficient and two approximation coefficients. FIG. 2 shows a diagram of wavelet reconstruction directly performed without processing the decomposition coefficients. FIG. 1 and FIG. 2 indicate that although s₀, s₃ and d₃ are distorted values, as long as values of extension points dⱼ₋₁ and x₈ remain consistent during decomposition and reconstruction, no matter what values the extension points take, they will not affect the reconstruction accuracy. However, this characteristic is of little significance in practical applications, because usually the use of wavelet transform to analyze and process the signal is to analyze and process the decomposition coefficients. Take wavelet thresholding denoising as an example, the decomposition coefficients must be thresholded before the reconstruction to obtain a denoised signal. Therefore, the distortion of the boundary wavelet coefficients will cause them to be improperly thresholded, thereby leading to reconstruction errors. FIG. 3 shows an extension of signal reconstruction after thresholding.

The distortion of s₀, s₃ and d₃ will cause the unreliability of ŝ₀, ŝ₃ and \hat{d}₃, and further causes the unreliability of \hat{x}₀, \hat{x}₁, \hat{x}₅, \hat{x}₆ and \hat{x}₇, thereby leading to reconstruction errors. In summary, for the signal sequence reconstructed after thresholding denoising in the one-layer decomposition of the CDF2.2 lifting wavelet, the two reconstructed values on the left and the three reconstructed values on the right are unreliable values due to the boundary interference.

For the online denoising of the MFL signal, if the real-time requirements are not very high, xₙ may be temporarily stored first, and then the sampling may continue for a period of time to acquire L future data fₗ for the right boundary of xₙ, that is, to complete a distortion-free extension of the right boundary of xₙ. At the same time, by the pre-storing, M historical data hₘ may be acquired for the left boundary of xₙ, that is, to complete a distortion-free extension of the left boundary of xₙ. In this way, the left and right boundary information of xₙ is completely supplemented, so that the signal \hat{x}ₙ of \hat{x}ₙ reconstructed by denoising is reliable. Compared with the current sampling point, the denoised signal output lags by L points. Therefore, this scheme is at the expense of sacrificing certain real-time performance to completely eliminate the boundary interference caused by the algorithm, and it is a distortion-free boundary extension scheme, as shown in FIG. 4.

The values of M and L are related to the wavelet basis used and the number of decomposition layers.

The values of M and L for the boundary extension are calculated below by taking the three-layer decomposition of a CDF2.2 wavelet lifting scheme as an example. In order to facilitate the calculation, it is assumed that the number of samples of x₂ₗ is a multiple of 8, so that the number of approximation coefficients of the first and second layers of decomposition are both even. According to FIG. 4:

Calculating d_{1,l} needs an extension of one point on the right of x₂ₗ;

Calculating s_{1,l} needs an extension of two points on the left of x₂ₗ;

Calculating d_{2,l} needs an extension of one point on the right of s_{1,l}, which is equivalent to an extension of two points on the right of x₂ₗ;

Calculating s_{2,l} needs an extension of two points on the left of s_{2,l}, which is equivalent to an extension of four points on the left of x₂ₗ;

Calculating d_{3,l} needs an extension of one point on the right of s_{2,1}, which is equivalent to an extension of two points on the right of s_{1,l}, and equivalent to an extension of four points on the right of x₂ₗ;

Calculating s_{3,l} needs an extension of two points on the left of s_{2,l}, which is equivalent to an extension of four points on the left of s_{1,l}, and equivalent to an extension of eight points on the left of x₂ₗ.

Therefore, the three-layer decomposition of the CDF2.2 wavelet lifting scheme needs to extend for a total of 2+4+8=14 points on the left and a total of 1+2+4=7 points on the right. That is, M=14, L=7.

It can be seen from the above that each additional layer of decomposition requires twice the number of extension points of the previous layer. For example, if the first layer of decomposition needs to extend m points to the left and l points to the right, then the second layer of decomposition needs to extend 2m points to the left and 2l points to the right, and the third layer of decomposition needs to extend 4m points to the left and 4l points to the right. Therefore, the total number M of left extension points and the total number L of right extension points required to decompose J layers can be summarized as:

M=m×(2^{j}−1)

L=l×(2^{j}−1) (1-2)

According to Eq. (1-2), the number of extension points required for the three-layer decomposition of the CDF2.6 (bior2.6) wavelet lifting scheme can be obtained. The CDF2.6 lifting scheme (with a normalization step ignored) is:

$$\{ \begin{matrix}{d}_{l} = {x}_{2 l + 1} - 0.5 \times ( {x}_{2 l} + {x}_{2 l + 2} ) \\ {s}_{l} = {x}_{2 l} + \frac{5 \times ( {d}_{l - 3} + {d}_{l + 2} ) - 39 \times ( {d}_{l - 2} + {d}_{l + 1} ) + 162 \times ( {d}_{l - 1} + {d}_{l} )}{512}\end{matrix} \qquad ( 1 \text{-} 3 )$$

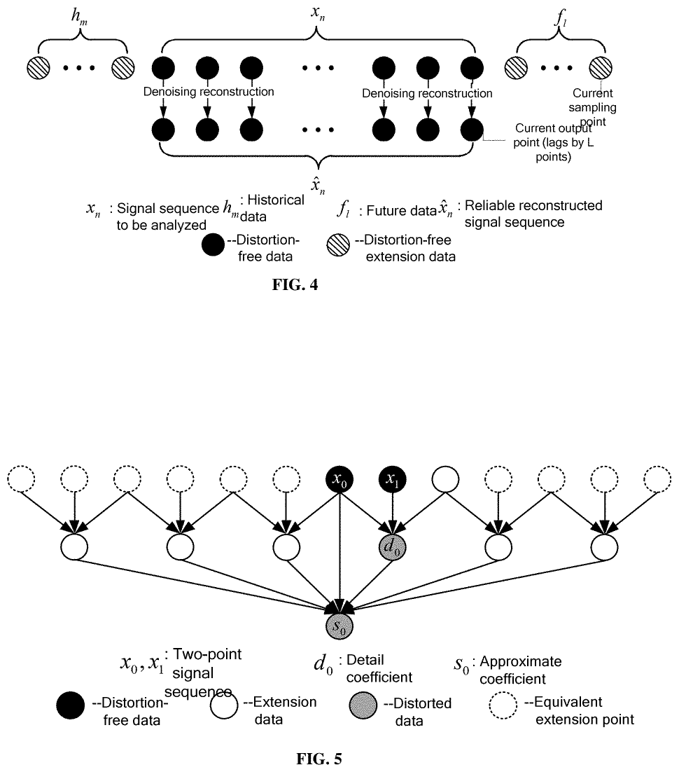

FIG. 5 shows an extension of one-layer decomposition of the CDF2.6 lifting scheme on a pair of sampling points (x₀,x₁). The one-layer decomposition of the CDF2.6 lifting scheme requires m=6 points to be extended on the left and l=5 points on the right. By substituting these two values into Eq. (1-2), the three-layer decomposition of the CDF2.6 lifting scheme needs to extend M=42 points on the left and L=35 points on the right. Therefore, for the wavelet decomposition of the online CDF2.6 lifting scheme of streaming data, the number of points required for the distortion-free extension is composed of M=42 historical data on the left and L=35 future data on the right. In this way, it can be ensured that the data will not be distorted by the boundary interference after denoising.

The distortion-free extension scheme cannot be realized at head and tail ends of the streaming data. Since the influence of the boundary interference on the accuracy of the entire algorithm is ignorable, the two parts of data are usually not processed or simply processed. However, in order to maximally suppress the boundary interference, the distortion-free extension scheme applies a symmetrical extension to the left boundary of the initial data segment and the right boundary of the final segment, and the number of extension points is M and L, respectively.

For a MFL curve, the sampling signal sequence is set to X, which is a one-dimensional discrete sequence that continues to grow over time. The present disclosure uses the lifting wavelet thresholding denoising algorithm to denoise X online and uses the distortion-free extension method to avoid the boundary interference of the lifting wavelet transform.

### Embodiment 1

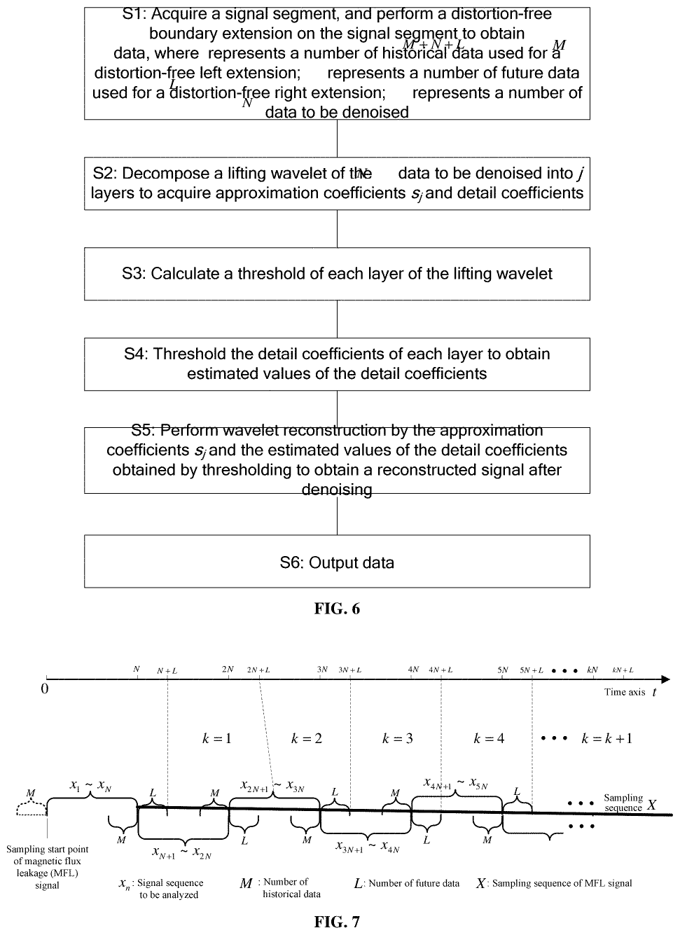

As shown in FIG. 6, a distortion-free boundary extension method for online wavelet denoising includes the following steps:

S1: Acquire a signal segment xₙ, and perform a distortion-free boundary extension on the signal segment to obtain M+N+L data, where M represents a number of historical data used for a distortion-free left extension; L represents a number of future data used for a distortion-free right extension; N represents a number of data to be denoised.

As shown in FIG. 7, a working time series for online denoising of the distortion-free extension scheme is as follows (assuming that a sampling interval is unit 1):

Preparation stage: Apply for a buffer area A that can hold M+N+L data. Here, an operation step named “sliding window operation” is defined as follows: once buffer A is full, the M+N+L data are output to a next-level wavelet denoiser within a sampling interval, the latter M+L data in buffer A are slid in the same order to the previous M+L spaces, and the remaining buffer space is cleared.

S101: Data start segment: Read, when 0<t≤N+L, N+L sampling points from a sampling start point.

S102: Symmetrically extend, when N+L<t<N+L+1, a left boundary of the N+L sampling points read for a length of M, and store in buffer A, that is, {x_{M+1},x_{M},x_{M-1}˜x₃,x₂,x₁,x₂,x₃˜x_{N+L}}; determine that buffer A is full, and perform a sliding window operation in A.

S103: Middle segment: Let k=1 be a cycle counter.

S104: Read, when kN+L+1≤t≤Kn+L+N, P sampling points into A; execute S105 if P=N; end a cycle and execute S107 if P<N.

S105: Determine, when kN+L+N<t<kN+L+N+1, that buffer A is full, and perform a sliding window operation in A.

S106: Let k=k+1, and return to S104.

S107: Data final segment: Determine that A is not full, set an end flag, and output the data in A to the wavelet denoiser. After receiving the end flag, the wavelet denoiser performs a symmetrical extension for a length of L on a right boundary of the received data and then performs denoising.

The wavelet denoiser receives the sampled data from buffer A, and performs denoising by a lifting wavelet thresholding method, and the denoised data is sent to a next level data compressor. The denoising of a previous group of data must be completed before the arrival of a latter group of data, that is, a denoising time Δt≤N. The specific method is as follows:

Data reception. The data received by the wavelet denoiser each time is a group of M+N+L in total, where the first M data are historical data used for a distortion-free left extension, the last L data are future data for a distortion-free right extension, and the middle N data are the current data to be denoised.

S2: Lifting wavelet decomposition

The lifting scheme is used to perform lifting wavelet three-layer decomposition on the middle N data xₙ to be denoised. The boundary extensions or distortion-free extensions required in the decomposition process are completed through the historical data and future data. The approximation coefficients are s₃, and the detail coefficients are {d₃,d₂,d₁}.

S3: Threshold calculation

According to detail coefficient d₁ of a first layer, a standard deviation σ of noise is estimated by using a median estimation method, and then a threshold Tⱼ of each layer is calculated:

$${T}_{j} = \frac{σ \sqrt{2 ln N}}{1 + 1 g j} , j = 1 , 2 , 3$$

S4: Thresholding

The detail coefficients {d₃,d₂,d₁} of each layer are thresholded by using a new thresholding function method to obtain estimated values {\hat{d}₃,\hat{d}₂,\hat{d}₁} of the detail coefficients:

$${\hat{d}}_{j} = {d}_{j} \times 1 {0}^{- {( \frac{{T}_{j}}{\vert {d}_{j} \vert + ɛ} )}^{γ}}$$

In the equation, γ is usually moderate to be γ=4, ε=10⁻⁵.

S5: Lifting wavelet reconstruction

Signal reconstruction is performed by the approximation coefficients s₃ and the detail coefficients {\hat{d}₃,\hat{d}₂,\hat{d}₁} obtained by thresholding to obtain a reconstructed signal \hat{x}ₙ after denoising. The boundary extension in the reconstruction remains consistent with that in the wavelet decomposition.

S6: Data output

The denoised signal \hat{x}ₙ is output to the next level of data compressor for further processing. At this point, the wavelet denoiser completes the denoising of one group of data, and then goes to S1.

In order to verify the denoising effect of the lifting algorithm of the present disclosure, the present disclosure performed a comparison analysis of simulation results as follows:

1. Comparison of Denoising Time Between the Lifting Algorithm and a Traditional Mallat Algorithm

By comparing the calculation amounts of the lifting algorithm of the present disclosure and the Mallat algorithm, it is concluded that the lifting algorithm is faster than the Mallat algorithm, with a speed increase up to 50%. In order to verify the correctness of the conclusion, a Matlab platform simulation experiment was designed as follows: a segment of noisy Bumps signal with a length of 1024 (SNR=9.6973 db) was selected, and different wavelet bases were applied for denoising. Each wavelet basis was implemented by using the lifting algorithm and the Mallat algorithm respectively. In order to eliminate the influence of other factors on the denoising performance, all experiments were conducted respectively by using a soft thresholding method and a Visushrink threshold estimation method, and the number of decomposition layers was 3, as shown in Table 1.

TABLE 1
Comparison of denoising time of different wavelet bases
processed by using lifting algorithm and Mallat algorithm

| | t/s | | | | t/s | | |
|---|---|---|---|---|---|---|---|
| | Mallat | Lifting | Decrease | | Mallat | Lifting | Decrease |
| db4 | 0.0712 | 0.0506 | 30.2% | sym4 | 0.0742 | 0.0513 | 30.9% |
| db5 | 0.0733 | 0.0505 | 31.1% | sym5 | 0.0727 | 0.0504 | 30.7% |
| db6 | 0.0712 | 0.0532 | 25.3% | sym6 | 0.0701 | 0.0501 | 28.6% |
| db7 | 0.0706 | 0.0513 | 27.3% | sym7 | 0.0724 | 0.0506 | 30.1% |
| db8 | 0.0723 | 0.0509 | 29.6% | sym8 | 0.0712 | 0.0510 | 28.4% |
| bior2.2 | 0.0730 | 0.0457 | 37.4% | bior2.8 | 0.0721 | 0.0467 | 35.2% |
| bior2.4 | 0.0742 | 0.0488 | 34.2% | bior4.4 | 0.0710 | 0.0455 | 35.9% |
| bior2.6 | 0.0724 | 0.0499 | 31.1% | bior6.8 | 0.0718 | 0.0468 | 34.8% |

It can be seen from Table 1 that compared with the traditional Mallat algorithm, the denoising time of the lifting algorithm is greatly decreased without exception by about 30%. This also proves that the wavelet denoising method using the lifting scheme can reduce the amount of calculation and speed up the calculation.

2. Comparison of Denoising Effect Between the Lifting Algorithm and Traditional Mallat Algorithm

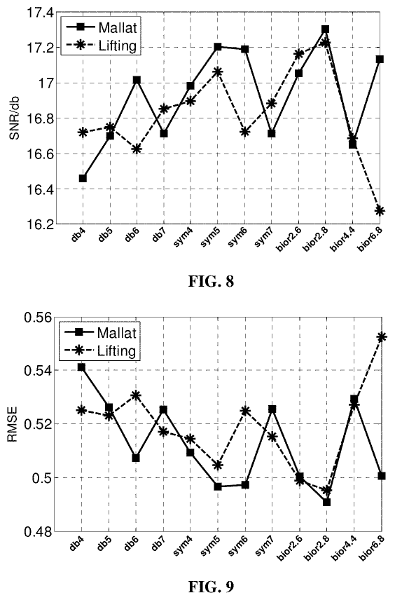

In order to prove that the wavelet thresholding denoising algorithm using the lifting scheme does not decrease the denoising performance, a Matlab platform simulation experiment was designed as follows: a segment of noisy Bumps signal with a length of 1024 (SNR=9.6973 db) was selected, and different wavelet bases were applied for denoising. Each wavelet basis was implemented by using the lifting algorithm and the Mallat algorithm respectively. In order to eliminate the influence of other factors on the denoising performance, all experiments were conducted respectively by using a soft thresholding method and a Visushrink threshold estimation method, and the number of decomposition layers was 3. Table 2 records the denoising performance data of different wavelet bases processed by using the lifting algorithm and the Mallat algorithm. Comparison diagrams were drawn based on the data in Table 2, as shown in FIGS. 8 and 9.

TABLE 2
Comparison of denoising performance of different wavelet bases
processed by using lifting algorithm and Mallat algorithm

| | Algorithm | SNR/db | RMSE | | Algorithm | SNR/db | RMSE |
|---|---|---|---|---|---|---|---|
| db4 | Traditional | 16.4592 | 0.5411 | sym4 | Traditional | 16.9838 | 0.5093 |
| | Lifting | 16.7185 | 0.5251 | | Lifting | 16.8984 | 0.5144 |
| db5 | Traditional | 16.7007 | 0.5262 | sym5 | Traditional | 17.2049 | 0.4966 |
| | Lifting | 16.7510 | 0.5232 | | Lifting | 17.0643 | 0.5047 |
| db6 | Traditional | 17.0169 | 0.5074 | sym6 | Traditional | 17.1912 | 0.4973 |
| | Lifting | 16.6261 | 0.5308 | | Lifting | 16.7240 | 0.5248 |
| db7 | Traditional | 16.7145 | 0.5254 | sym7 | Traditional | 16.7118 | 0.5256 |
| | Lifting | 16.8537 | 0.5170 | | Lifting | 16.8822 | 0.5153 |
| bior2.6 | Traditional | 17.0538 | 0.5003 | bior4.4 | Traditional | 16.6509 | 0.5293 |
| | Lifting | 17.1651 | 0.4988 | | Lifting | 16.6859 | 0.5271 |
| bior2.8 | Traditional | 17.3050 | 0.4909 | bior6.8 | Traditional | 17.1340 | 0.5006 |
| | Lifting | 17.2291 | 0.4952 | | Lifting | 16.2755 | 0.5526 |

It can be seen from FIGS. 8 and 9 that under the same wavelet basis, the lifting algorithm and the traditional algorithm do not significantly enhance or weaken the denoising effect of the signal, and usually have a very small difference in the denoising effect. This shows that the denoising performance of wavelet denoising using the lifting algorithm is not worse or significantly better than that of the traditional Mallat algorithm.

3. Comparison of Denoising Performance of Different Thresholding Functions

A Matlab platform simulation test was designed as follows: a segment of noisy Bumps signal with a length of 1024 was selected; a soft thresholding method, a hard thresholding method, a flattening method and the new thresholding function method proposed by the present disclosure were used for denoising, and their results were compared. In order to eliminate the influence of other factors on the denoising performance, all experimental wavelet bases were sym5 wavelets to improve the decomposition of the schemes; the number of decomposition layers was 3; the thresholds were estimated layer by layer. The experiment was conducted on noisy signals with SNR=11.1257 db and SNR=17.1421 db, respectively. The denoising effects and evaluation indexes of the four denoising methods are shown in Table 3.

TABLE 3
Comparison of denoising performance
of different thresholding functions

| | SNR/db | RMSE | | SNR/db | RMSE |
|---|---|---|---|---|---|
| Noisy signal | 11.1257 | 0.9740 | Noisy signal | 17.1421 | 0.9745 |
| Hard threshold- | 17.3231 | 0.4772 | Hard threshold- | 20.7279 | 0.6449 |
| ing method | | | ing method | | |
| Soft threshold- | 17.9591 | 0.4435 | Soft threshold- | 21.6709 | 0.5785 |
| ing method | | | ing method | | |
| Flattening | 18.6803 | 0.4082 | Flattening | 23.2430 | 0.4827 |
| method | | | method | | |
| Method of the | 18.7938 | 0.4029 | Method of the | 23.4126 | 0.4689 |
| present | | | present | | |
| disclosure | | | disclosure | | |

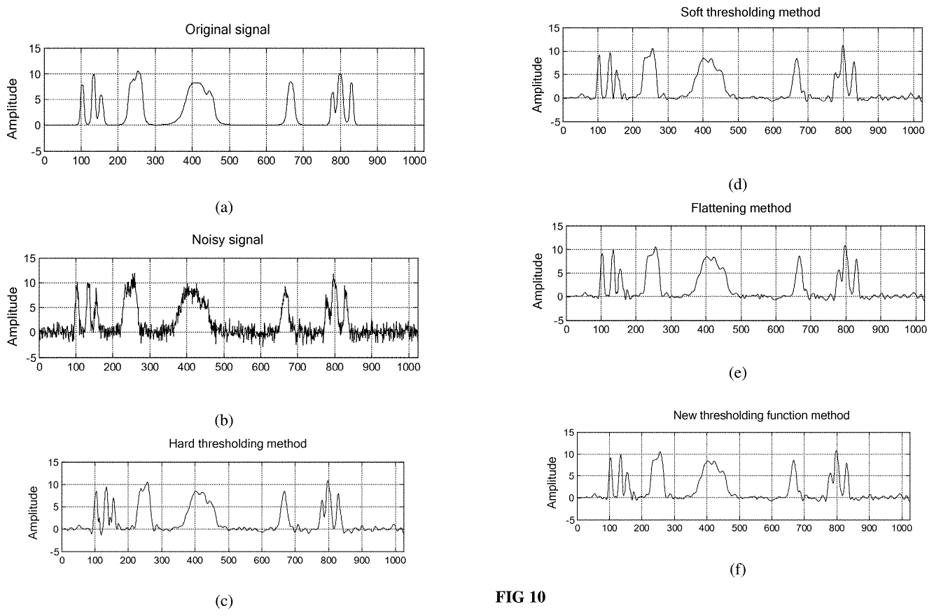

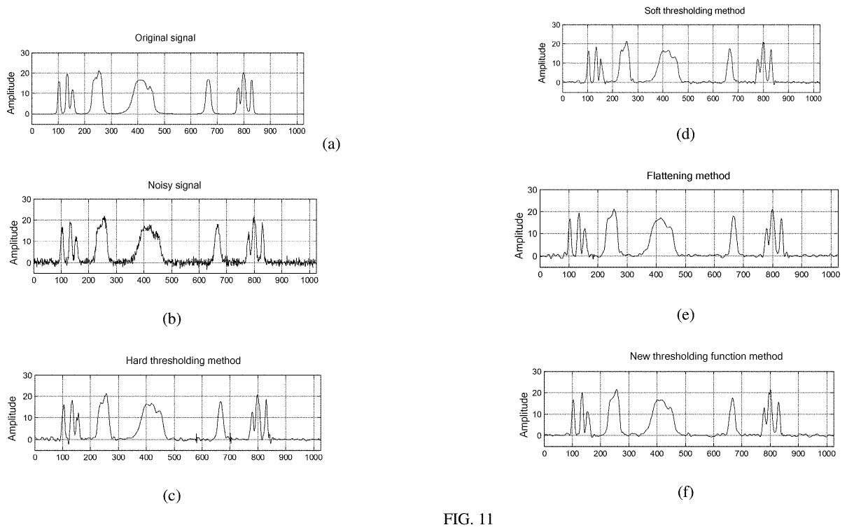

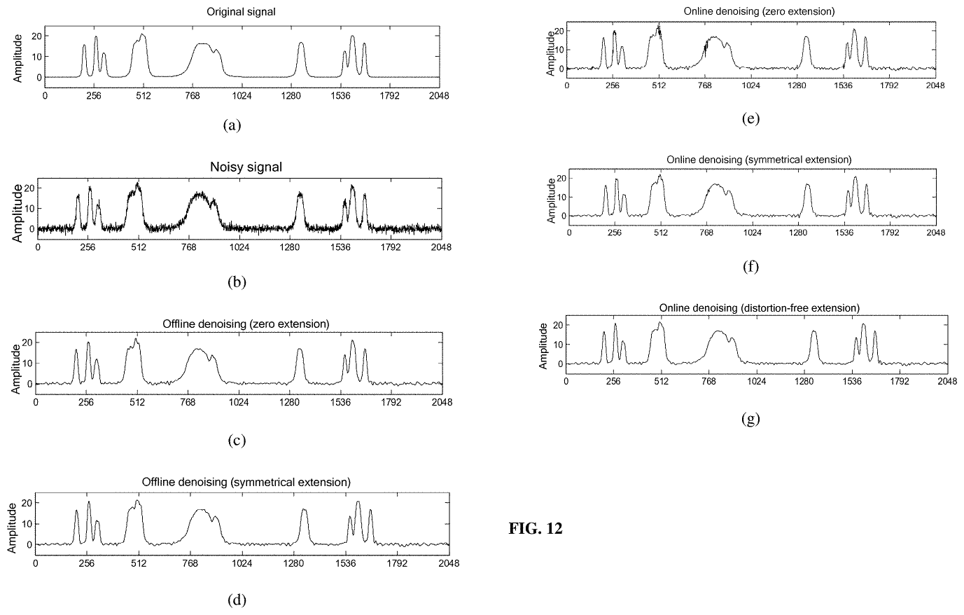

In FIG. 10, FIG. 10(a) shows an original signal waveform; FIG. 10(b) shows a noisy signal waveform; FIG. 10(c) shows a denoising result of the hard thresholding method; FIG. 10(d) shows a denoising result of the soft thresholding method; FIG. 10(e) shows a denoising result of the flattening method; 10(f) shows a denoising result of the new thresholding function method. In FIG. 11, FIG. 11(a) shows an original signal waveform; FIG. 11(b) shows a noisy signal waveform; FIG. 11(c) shows a denoising result of the hard thresholding method; FIG. 11(d) shows a soft thresholding method; FIG. 11(e) shows a denoising result of the flattening method; FIG. 11(f) shows a denoising result of the new thresholding function method. It can be seen from FIG. 10 and FIG. 11 that compared with other methods, in the hard thresholding method, the signal has some roughness after being processed. The curve of the soft thresholding method is smooth, but compared with the original pure signal, some useful details are eliminated. Table 3 shows that the signal-to-noise ratios (SNRs) after denoising by the soft and hard thresholding methods are low, while the root-mean-square errors (RMSE) are high, which proves that the soft and hard thresholding methods are defective. The processing results of the flattening method reproduce the original pure signal better, with a higher SNR and a lower RMSE, indicating that the flattening method is superior to the soft and hard thresholding methods. The new thresholding function denoising method proposed by the present disclosure achieves the highest SNR and the lowest RMSE, indicating that the denoised signal processed by this method more completely restores the real signal, and the denoising performance of the method is the best. The above results prove the feasibility and superiority of the new thresholding function method proposed by the present disclosure.

4. Performance Verification of Distortion-Free Extension Schemes

A Matlab platform simulation experiment was designed as follows: a noisy Bumps signal with a length of 2048 (SNR=16.9773 db) was selected; a zero extension scheme and a symmetric extension scheme were first used for offline signal denoising, and then the zero extension scheme, the symmetric extension scheme and the distortion-free extension scheme were respectively used for online signal denoising. In order to eliminate the influence of other factors on the denoising performance, all experimental wavelet bases were sym5 wavelets to improve the decomposition of the schemes; the number of decomposition layers was 3; the thresholds were estimated layer by layer. In offline denoising, all 2048 data were processed at one time; in online processing, 256 data points were processed in each segment. The denoising effects and denoising performance evaluation indexes of these five denoising schemes under the two environments are shown in FIG. 12 and Table 4 respectively. In FIG. 12, FIG. 12(a) shows an original signal waveform; FIG. 12(b) shows a noisy signal waveform; FIG. 12(c) shows an offline denoising result of the zero extension scheme; FIG. 12(d) shows an offline denoising result of the symmetric extension scheme; FIG. 12(e) shows an online denoising result of the zero extension scheme; FIG. 12(f) shows an online denoising result of the symmetric extension scheme; FIG. 12(g) shows an online denoising result of the distortion-free extension scheme.

TABLE 4
Denoising performance of different extension schemes

| | | SNR/db | RMSE |
|---|---|---|---|
| Noisy signal | — | 16.9773 | 0.9935 |
| Zero extension | Offline | 25.1328 | 0.3885 |
| | Online | 22.9576 | 0.4990 |
| Symmetrical extension | Offline | 25.1898 | 0.3859 |
| | Online | 24.8795 | 0.4000 |
| Distortion-free extension | Online | 25.2588 | 0.3834 |

According to Table 4 and FIG. 12:

(1) The offline and online denoising effects of the symmetric extension scheme are always better than those of the zero extension scheme.

(2) In the offline denoising environment, the boundary interference mainly occurs at the head and tail ends, which has little impact on the overall denoising effect. Although the zero extension scheme is the least effective, it can get a higher SNR after denoising.

(3) For the zero extension scheme and the symmetric extension scheme in the online denoising environment, in addition to the boundary interference at the head and tail ends, there is also a boundary interference occurring at every 256 points in the middle segment, resulting in poor denoising effect. The boundary interference of the zero extension scheme is particularly serious; the symmetric extension scheme can suppress the boundary interference, but it cannot completely eliminate the boundary interference.

(4) By completely eliminating the boundary interference in the middle segment and applying the symmetric extension scheme to suppress the boundary interference at the head and tail ends, the distortion-free extension scheme maximally suppresses the boundary interference as a whole, and achieves the best denoising effect. It can be seen from the SNR and RMSE data in Table 3 that the distortion-free extension scheme achieves the same or even better denoising performance in the online environment as in the offline environment.

The above simulation experiments prove that the distortion-free extension scheme can suppress the boundary interference during online denoising to the greatest extent, and obtain a denoising effect not inferior to that in the offline environment.

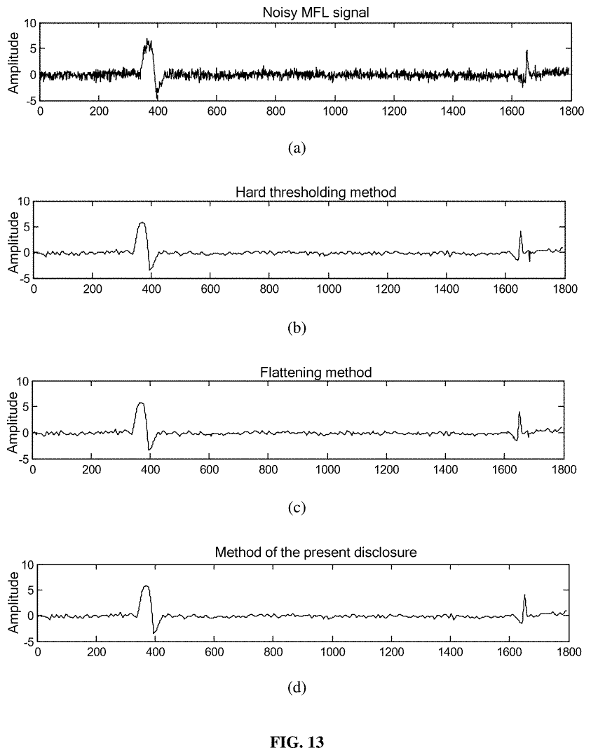

Denoising experiments were conducted with an actual MFL signal as follows: a segment of noisy MFL signal with a length of 1792 was selected; the hard thresholding method, the flattening method and the new thresholding function method proposed by the present disclosure were used for denoising respectively, and their results were compared. In order to eliminate the influence of other factors on the denoising performance, all experimental wavelet bases were sym5 wavelets to improve the decomposition of the schemes; the number of decomposition layers was 3; the thresholds were estimated layer by layer. The denoising process was completed by using the distortion-free extension scheme online. The comparison of the denoising effects of the three denoising methods is shown in FIG. 13. In FIG. 13, FIG. 13(a) shows a noisy MFL signal; FIG. 13(b) shows a denoising result of the hard thresholding method; FIG. 13(c) shows a denoising result of the flattening method; FIG. 13(d) shows a denoising result of the method of the present disclosure. It can be seen from the comparison diagrams that although the traditional hard thresholding method can eliminate part of the noise influence, the signal has a pseudo Gibbs phenomenon after processing, which is not as smooth as signals processed by using other methods. The flattening method has a certain improvement over the hard thresholding method, and the denoising effect is satisfactory, with a smooth curve and full details. The denoising method proposed by the present disclosure has a further improvement in the performance compared with the flattening method, and the denoising effect is the best among the three methods; the curve is the smoothest, better retaining the subtle features of the signal and better restoring the actual MFL signal generated from a defect. The test results prove that the denoising method proposed by the present disclosure is feasible and has excellent performance in the online denoising of the MFL signal.

### Embodiment 2

The present disclosure further provides a distortion-free boundary extension device for online wavelet denoising, including a distortion-free boundary extension module and a wavelet denoiser.

The distortion-free boundary extension module is used for performing a distortion-free boundary extension on an acquired signal segment to obtain M+N+L data, where M represents a number of historical data used for a distortion-free left extension; L represents a number of future data used for a distortion-free right extension; N represents a number of data to be denoised.

The wavelet denoiser is used for decomposing a lifting wavelet of the N data to be denoised into j layers to acquire approximation coefficients sⱼ and detail coefficients {dⱼ, . . . , d₂,d₁}, calculating a threshold Tⱼ of each layer of the lifting wavelet, thresholding the detail coefficients {dⱼ, . . . , d₂,d₁} of each layer to obtain estimated values of the detail coefficients, performing wavelet reconstruction by the approximation coefficients sⱼ and the estimated values of the detail coefficients obtained by thresholding to obtain a reconstructed signal \hat{x}ₙ after denoising, and outputting data.

The distortion-free boundary extension performed by the distortion-free boundary extension module includes:

S101: Read, when 0<t≤N+L, N+L sampling points from a sampling start point.

S102: Symmetrically extend, when N+L<t<N+L+1, a left boundary of the N+L sampling points read for a length of M, and store in a buffer A; output, if buffer A is full, data in A to a next-level wavelet denoiser, slide latter M+L data in buffer A to former M+L spaces in the same order, and clear a remaining buffer space.

S103: Let k be a cycle counter, k=1.

S104: Read, when kN+L+1≤t≤kN+L+N, P sampling points into A; execute S105 if P=N; execute S107 if P<N.

S105: Determine, when kN+L+N<t<kN+L+N+1, that buffer A is full, and perform a sliding window operation in A.

S106: Let k=k+1, and return to S104.

S107: End.

The wavelet denoiser calculates the threshold Tⱼ of each layer of the lifting wavelet as follows:

$${T}_{j} = \frac{σ \sqrt{2 ln N}}{1 + 1 g j} , j = 1 , 2 , 3 .$$

The wavelet denoiser thresholds the detail coefficients {dⱼ, . . . , d₂,d₁} of each layer to obtain the estimated values of the detail coefficients as follows:

$${\hat{d}}_{j} = {d}_{j} \times 1 {0}^{- {( \frac{{T}_{j}}{\vert {d}_{j} \vert + ɛ} )}^{γ}}$$

where, γ=4, ε=10⁻⁵.

### Embodiment 3

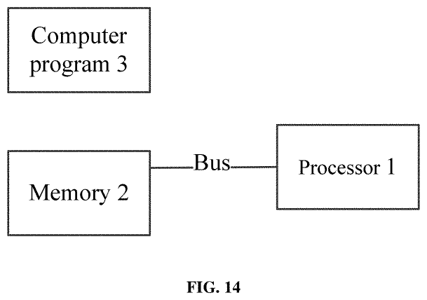

This embodiment provides an electronic device. According to a schematic diagram of a hardware structure of the electronic device in FIG. 14, the electronic device includes a processor 1, a memory 2 and a computer program 3.

The memory is used for storing the computer program, and the memory may be a flash memory. The computer program may be, for example, an application program or a function module for implementing the above-mentioned method.

The processor runs the computer program to implement the following steps:

S1: Acquire a signal segment xₙ, and perform a distortion-free boundary extension on the signal segment to obtain M+N+L data, where M represents a number of historical data used for a distortion-free left extension; L represents a number of future data used for a distortion-free right extension; N represents a number of data to be denoised.

In S1, the distortion-free boundary extension processing includes:

S101: Read, when 0<t≤N+M, N+M sampling points from a sampling start point.

S102: Symmetrically extend, when N+M<t<N+M+1, a left boundary of the N+M sampling points read for a length of M, and store in a buffer A; output, if buffer A is full, data in A to a next-level wavelet denoiser, slide latter M+N data in buffer A to former M+N spaces in the same order, and clear a remaining buffer space.

S103: Let k be a cycle counter, k=1.

S104: Read, when kN+M+1≤t≤kN+M+N, P sampling points into A; execute S105 if P=N; execute S107 if P<N.

S105: Determine, when kN+M+N<t<kN+M+N+1, that buffer A is full, and perform a sliding window operation in A.

S106: Let k=k+1, and return to S104.

S107: End.

S108: Acquire, when performing distortion-free boundary extension processing on a k-th signal segment, M historical data in a (k−1)-th signal segment in buffer A, to-be-denoised data in the k-th signal segment and L future data in a (k+1)-th signal segment to generate M+N+L data used for the distortion-free boundary extension processing on the k-th signal segment.

S2: Decompose a lifting wavelet of the N data to be denoised into j layers according to the historical data and the future data to acquire an approximation coefficient sⱼ and detail coefficients {dⱼ, . . . , d₂,d₁}.

In S2, the wavelet is decomposed into j≤3 layers.

The S2 of decomposing a lifting wavelet of the N data to be denoised into j layers according to the historical data and the future data to acquire an approximation coefficient sj and detail coefficients {dⱼ, . . . , d₂,d₁} specifically includes:

Acquire, from the historical data, data used for a left boundary of the N data to be denoised during the j-layer decomposition of the lifting wavelet.

Acquire, from the future data, data used for a right boundary of the N data to be denoised during the j-layer decomposition of the lifting wavelet.

S3: Calculate a threshold Tⱼ of each layer of the lifting wavelet.

In S3, the threshold Tⱼ of each layer of the lifting wavelet is calculated as follows:

$${T}_{j} = \frac{σ \sqrt{2 ln N}}{1 + 1 g j} , j = 1 , 2 , 3$$

where, σ represents a standard deviation of noise.

S4: Threshold the detail coefficients {dⱼ, . . . , d₂,d₁} of each layer to obtain estimated values of the detail coefficients.

In S4, the estimated values of the detail coefficients obtained by thresholding the detail coefficients {dⱼ, . . . , d₂,d₁} of each layer are:

$${\hat{d}}_{j} = {d}_{j} \times 1 {0}^{- {( \frac{{T}_{j}}{\vert {d}_{j} \vert + ɛ} )}^{γ}}$$

where, γ=4, ε=10⁻⁵.

S5: Perform wavelet reconstruction by the approximation coefficients sⱼ and the estimated values of the detail coefficients obtained by thresholding to obtain a reconstructed signal \hat{x}ₙ after denoising.

A boundary extension in the reconstruction in S5 remains consistent with that in the wavelet decomposition in S2.

Optionally, the memory may be independent from or integrated with the processor.

When the memory is independent from the processor, the electronic device may further include:

a bus, for connecting the memory and the processor.

The electronic device may specifically be a computer terminal, a server, or a computer system with a display.

The present disclosure further provides a readable storage medium. The readable storage medium stores a computer program; the computer program is executed by a processor to implement the above-mentioned methods provided in various implementations.

The readable storage medium may be a computer storage medium or a communication medium. The communication medium includes any medium that facilitates the transfer of the computer program from one place to another. The computer storage medium may be any available medium that can be accessed by a general-purpose or special-purpose computer. For example, the readable storage medium is coupled to the processor, so that the processor can read information from the readable storage medium and write information into the readable storage medium. Certainly, the readable storage medium may alternatively be a component of the processor. The processor and the readable storage medium may be located in an application-specific integrated circuit (ASIC), and the ASIC may be located in a user device. Of course, the processor and the readable storage medium may also exist as discrete components in a communication device.

The present disclosure further provides a program product. The program product includes an execution instruction stored in a readable storage medium. At least one processor of the device can read the execution instruction from the readable storage medium, and the execution of the execution instruction by the at least one processor causes the device to implement the above-mentioned methods provided in various implementations.

It should be understood that in the embodiments of the above-mentioned electronic device, the processor may be a central processing unit (CPU), other general-purpose processor or digital signal processors (DSP), or an ASIC. The general-purpose processor may be a microprocessor or any conventional processor. The steps of each method disclosed by the embodiments of the present disclosure may be directly performed by a hardware processor, or by a combination of hardware and software modules in a processor.

The above described are merely specific implementations of the present disclosure, and the protection scope of the present disclosure is not limited thereto. Any modification or replacement easily conceived by those skilled in the art within the technical scope of the present disclosure should fall within the protection scope of the present disclosure. Therefore, the protection scope of the present disclosure should be subject to the protection scope of the claims.

Without further elaboration, it is believed that one skilled in the art can, using the preceding description, utilize the present invention to its fullest extent. The preceding preferred specific embodiments are, therefore, to be construed as merely illustrative, and not limitative of the remainder of the disclosure in any way whatsoever.

In the foregoing and in the examples, all temperatures are set forth uncorrected in degrees Celsius and, all parts and percentages are by weight, unless otherwise indicated.

The entire disclosures of all applications, patents and publications, cited herein and of corresponding Chinese application No. 202010345709.0, filed Apr. 27, 2020, are incorporated by reference herein.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

What is claimed is:

1. A distortion-free boundary extension method for online wavelet denoising, comprising the following steps:
S1: acquiring a signal segment xₙ, and performing a distortion-free boundary extension on the signal segment to obtain M+N+L data, wherein M represents a number of historical data used for a distortion-free left extension; L represents a number of future data used for a distortion-free right extension; N represents a number of data to be denoised;
S2: decomposing a lifting wavelet of the N data to be denoised into j layers to acquire approximation coefficients sⱼ and detail coefficients {dⱼ, . . . , d₂,d₁};
S3: calculating a threshold Tⱼ of each layer of the lifting wavelet;
S4: thresholding the detail coefficients {dⱼ, . . . , d₂,d₂} of each layer to obtain estimated values of the detail coefficients;
S5: performing wavelet reconstruction by the approximation coefficients sⱼ and the estimated values of the detail coefficients obtained by thresholding to obtain a reconstructed signal \hat{x}ₙ after denoising; and
S6: outputting data.

2. The distortion-free boundary extension method for online wavelet denoising according to claim 1, wherein in S1, the distortion-free boundary extension comprises:
S101: reading, when 0<t≤N+L, N+L sampling points from a sampling start point;
S102: symmetrically extending, when N+L<t<N+L+1, a left boundary of the N+L sampling points read for a length of M, and storing in a buffer A; outputting, if buffer A is full, data in A to a next-level wavelet denoiser, and sliding latter M+L data in buffer A to former M+L spaces in the same order, and clearing a remaining buffer space;
S103: letting k be a cycle counter, k=1;
S104: reading, when kN+L+1≤t≤kN+L+N, P sampling points into A; executing S105 if P=N; executing S107 if P<N;
S105: determining, when kN+L+N<t<kN+L+N+1, that buffer A is full, and performing a sliding window operation in A;
S106: letting k=k+1, and returning to S104; and
S107: ending.

3. The distortion-free boundary extension method for online wavelet denoising according to claim 1, wherein in S3, the threshold Tⱼ of each layer of the lifting wavelet is calculated as follows:
$${T}_{j} = \frac{σ \sqrt{2 ln N}}{1 + 1 g j} , j = 1 , 2 , 3$$
wherein, σ represents a standard deviation of noise.

4. The distortion-free boundary extension method for online wavelet denoising according to claim 2, wherein in S3, the threshold Tⱼ of each layer of the lifting wavelet is calculated as follows:
$${T}_{j} = \frac{σ \sqrt{2 ln N}}{1 + 1 g j} , j = 1 , 2 , 3$$
wherein, σ represents a standard deviation of noise.

5. The distortion-free boundary extension method for online wavelet denoising according to claim 3, wherein in S4, the estimated values of the detail coefficients obtained by thresholding the detail coefficients {dⱼ, . . . , d₂,d₁} of each layer are:
$${\hat{d}}_{j} = {d}_{j} \times 1 {0}^{- {( \frac{{T}_{j}}{\vert {d}_{j} \vert + ɛ} )}^{γ}}$$
wherein, γ=4, ε=10⁻⁵.

6. The distortion-free boundary extension method for online wavelet denoising according to claim 4, wherein in S4, the estimated values of the detail coefficients obtained by thresholding the detail coefficients {dⱼ, . . . , d₂,d₁} of each layer are:
$${\hat{d}}_{j} = {d}_{j} \times 1 {0}^{- {( \frac{{T}_{j}}{\vert {d}_{j} \vert + ɛ} )}^{γ}}$$
wherein, γ=4, ε=10⁻⁵.

7. The distortion-free boundary extension method for online wavelet denoising according to claim 1, wherein a boundary extension in the reconstruction in S5 remains consistent with that in the wavelet decomposition in S2.

8. The distortion-free boundary extension method for online wavelet denoising according to claim 1, wherein in S2, the wavelet is decomposed into j≤3 layers.

9. A distortion-free boundary extension device for online wavelet denoising, comprising a distortion-free boundary extension module and a wavelet denoiser, wherein
the distortion-free boundary extension module is used for performing a distortion-free boundary extension on an acquired signal segment to obtain M+N+L data, wherein M represents a number of historical data used for a distortion-free left extension; L represents a number of future data used for a distortion-free right extension; N represents a number of data to be denoised;
the wavelet denoiser is used for decomposing a lifting wavelet of the N data to be denoised into j layers to acquire approximation coefficients sⱼ and detail coefficients {dⱼ, . . . , d₂,d₁}, calculating a threshold Tⱼ of each layer of the lifting wavelet, thresholding the detail coefficients {dⱼ, . . . , d₂,d₁} of each layer to obtain estimated values of the detail coefficients, performing wavelet reconstruction by the approximation coefficients sⱼ and the estimated values of the detail coefficients obtained by thresholding to obtain a reconstructed signal \hat{x}ₙ after denoising, and outputting data.

10. The distortion-free boundary extension device for online wavelet denoising according to claim 9, wherein the wavelet denoiser calculates the threshold Tⱼ of each layer of the lifting wavelet as follows:
$${T}_{j} = \frac{σ \sqrt{2 ln N}}{1 + lgj} , j = 1 , 2 , 3$$
the estimated values of the detail coefficients obtained by thresholding the detail coefficients {dⱼ, . . . , d₂,d₁} of each layer are:
$${\hat{d}}_{j} = {d}_{j} \times 1 {0}^{- {( \frac{{T}_{j}}{\vert {d}_{j} \vert + ɛ} )}^{γ}}$$
wherein, γ=4, ε=10⁻⁵.

11. An electronic device, comprising a memory, a processor and a computer program, wherein the computer program is stored in the memory, and the processor runs the computer program to execute the following steps:
S1: acquiring a signal segment xₙ, and performing a distortion-free boundary extension on the signal segment to obtain M+N+L data, wherein M represents a number of historical data used for a distortion-free left extension; L represents a number of future data used for a distortion-free right extension; N represents a number of data to be denoised;
S2: decomposing a lifting wavelet of the N data to be denoised into j layers according to the historical data and the future data to acquire approximation coefficients sⱼ and detail coefficients {dⱼ, . . . , d₂,d₁};
S3: calculating a threshold Tⱼ of each layer of the lifting wavelet;
S4: thresholding the detail coefficients {dⱼ, . . . , d₂,d₁} of each layer to obtain estimated values of the detail coefficients;
S5: performing wavelet reconstruction by the approximation coefficients sⱼ and the estimated values of the detail coefficients obtained by thresholding to obtain a reconstructed signal \hat{x}ₙ after denoising; and
S6: outputting data.

12. The electronic device according to claim 11, wherein in S1, the distortion-free boundary extension comprises:
S101: reading, when 0<t≤N+M, N+M sampling points from a sampling start point;
S102: symmetrically extending, when N+M<t<N+M+1, a left boundary of the N+M sampling points read for a length of M, and storing in a buffer A; outputting, if buffer A is full, data in A to a next-level wavelet denoiser, and sliding latter M+N data in buffer A to former M+N spaces in the same order, and clearing a remaining buffer space;
S103: letting k be a cycle counter, k=1;
S104: reading, when kN+M+1≤t≤kN+M+N, P sampling points into A; executing S105 if P=N; executing S107 if P<N;
S105: determining, when kN+M+N<t<kN+M+N+1, that buffer A is full, and performing a sliding window operation in A;
S106: letting k=k+1, and returning to S104;
S107: ending; and
S108: acquiring, when performing a distortion-free boundary extension on a k-th signal segment, M historical data in a (k−1)-th signal segment in buffer A, to-be-denoised data in the k-th signal segment and L future data in a (k+1)-th signal segment to generate M+N+L data used for the distortion-free boundary extension on the k-th signal segment.

13. The electronic device according to claim 11, wherein in S3, the threshold Tⱼ of each layer of the lifting wavelet is calculated as follows:
$${T}_{j} = \frac{σ \sqrt{2 ln N}}{1 + lgj} , j = 1 , 2 , 3$$
wherein, σ represents a standard deviation of noise.

14. The electronic device according to claim 12, wherein in S3, the threshold Tⱼ of each layer of the lifting wavelet is calculated as follows:
$${T}_{j} = \frac{σ \sqrt{21 n N}}{1 + lgj} , j = 1 , 2 , 3$$
wherein, σ represents a standard deviation of noise.

15. The electronic device according to claim 13, wherein in S4, the estimated values of the detail coefficients obtained by thresholding the detail coefficients {dⱼ, . . . , d₂,d₁} of each layer are:
$${\hat{d}}_{j} = {d}_{j} \times 1 {0}^{- {( \frac{{T}_{j}}{\vert {d}_{j} \vert + ɛ} )}^{γ}}$$
wherein, γ=4, ε=10⁻⁵.

16. The electronic device according to claim 14, wherein in S4, the estimated values of the detail coefficients obtained by thresholding the detail coefficients {dⱼ, . . . , d₂,d₁} of each layer are:
$${\hat{d}}_{j} = {d}_{j} \times 1 {0}^{- {( \frac{{T}_{j}}{\vert {d}_{j} \vert + ɛ} )}^{γ}}$$
wherein, γ=4, ε=10⁻⁵.

17. The electronic device according to claim 11, wherein a boundary extension in the reconstruction in S5 remains consistent with that in the wavelet decomposition in S2.

18. The electronic device according to claim 11, wherein in S2, the wavelet is decomposed into j≤3 layers.

19. The electronic device according to claim 11, wherein the S2: decomposing a lifting wavelet of the N data to be denoised into j layers according to the historical data and the future data to acquire approximation coefficients sⱼ and detail coefficients {dⱼ, . . . , d₂,d₁} specifically comprises:
acquiring, from the historical data, data used for a left boundary of the N data to be denoised during the j-layer decomposition of the lifting wavelet; and
acquiring, from the future data, data used for a right boundary of the N data to be denoised during the j-layer decomposition of the lifting wavelet.
